(19) United States
(12) Patent Application Publication
(10) Pub. No.: US 2005/0285234 A1
(43) Pub. Date: Dec. 29, 2005

(54) High-frequency circuit

(76) Inventor: Hiroshi Kanno, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/203,194

(22) Filed: Aug. 15, 2005

Related U.S. Application Data
(63) Continuation of application No. PCT/JP04/01993, filed on Feb. 20, 2004.

(30) Foreign Application Priority Data
Feb. 21, 2003 (JP) 2003-044530

(51) Int. Cl. H01L 29/40; H01L 23/34

(52) U.S. Cl. 257/664; 257/728; 257/700

(57) ABSTRACT

According to the present invention, provided is a high-frequency circuit having a high-frequency functional element mounted on a dielectric substrate, which comprises: a first transmission line formed in the high-frequency functional element; a second transmission line having a characteristic impedance lower than or equal to 50Ω and formed on the dielectric substrate; a wire for connecting between the first transmission line and the second transmission line; a third transmission line having a characteristic impedance higher than 50Ω and connected to the second transmission line; a via hole section which is formed so as to pass through the dielectric substrate and in which a top side conductive land is connected to the third transmission line; and a fourth transmission line connected to a bottom side conductive land of the via hole section.

This application is a continuation of International Application PCT/JP2004/001993, filed Feb. 20, 2004.

### BACKGROUND OF THE INVENTION

1. Field of the Invention

The present invention relates to a high-frequency circuit for use in a millimeter wave range, and more particularly to a high-frequency circuit used around portions to which a high-frequency functional element is wire-bonded.

2. Description of the Background Art

In recent years, a communication speed is further increased, and thereby a carrier frequency used for radio communication is reaching a frequency band of millimeter wave domain beyond a microwave domain. As the frequency becomes higher, inductance of a wire connecting portion cannot be neglected. Therefore, reflection is increased at an input/output portion of a semiconductor element used for high frequency, the input/output portion being connected to a wire in a system. Therefore, there is a problem that characteristics typical of a semiconductor element used for high frequency cannot be sufficiently obtained.

In “Interconnect and Packaging Technologies for Microwave and Millimeter-wave Circuits” (General Conference of the Institute of Electronics, Information and Communication Engineers, TC-1-1, 1999) (hereinafter, referred to as Document 1), a method for reducing inductance in a wire connecting portion is suggested. The Document 1 discloses a method for reducing inductance in a wire connecting portion by shortening a length of the wire, using a ribbon-type wire, flip-chip bonding using a through hole, etc., and the like.

A surface-mount package for enabling a high-frequency functional element to be mounted by surface mounting (hereinafter, referred to as a high frequency package) has been developed for a millimeter wave range as has been conventionally performed in a low frequency band. A wire is used in the high frequency package so as to connect between the high-frequency functional element and a signal strip on a dielectric substrate.

FIG. 16A is a cross-sectional view illustrating a configuration outline in the case of a conventional high frequency package being surface-mounted on an external circuit substrate. As shown in FIG. 16A, a high-frequency functional element 2 is accommodated in a cavity formed by a dielectric substrate 1 and a cover 33. FIG. 16B is a diagram illustrating a wiring pattern of a top surface of the dielectric substrate 1. FIG. 16C is a diagram illustrating a wiring pattern of a bottom surface of the dielectric substrate 1.

As shown in FIG. 16B, a ground conductive area 12, a signal strip 34, and a ground conductive layer 35 are formed on the top surface of the dielectric substrate 1. As shown in FIG. 16C, a ground conductive area 13, a ground strip 37, and a signal strip 36 are formed on the bottom surface of the dielectric substrate 1. On the dielectric substrate 1, a ground-added coplanar strip line configuration is composed of the signal strip 36, the ground conductive layer 35, and the ground strip 37. An external circuit substrate 38 on which the high-frequency package is surfaced-mounted has a signal strip 39 formed on a top surface thereof, and a ground strip 40 formed on at least one of the inside and bottom surface thereof. In the external circuit substrate, a high frequency transmission line configuration such as a microstrip line or a ground-added coplanar strip line is composed of the signal strip 39 and the ground strip 40.

One end of the signal strip 34 is connected to the high-frequency functional element 2 by a wire 5. The other end of the signal strip 34 is connected to one end of a connecting through-via 7 which is formed so as to pass through the dielectric substrate 1. One end of the signal strip 36 is connected to the other end of the connecting through-via 7. The other end of the signal strip 36 is connected to the signal strip 39 on the external circuit substrate 38 via a solder 41. A high frequency signal is input into/output from the high-frequency functional element 2 via the wire 5, the signal strip 34, the connecting through-via 7, the signal strip 36, the solder 41, and the signal strip 39.

As described above, in a conventional high frequency package, a high frequency signal is transmitted via a wire. Therefore, it is necessary to reduce reflection at a connecting portion of the wire.

As disclosed in the Document 1, a length of the wire can be shortened, and thereby inductance can be reduced at the connecting portion of the wire, thereby enabling the reflection to be reduced. However, there are limits to shortening the length of the wire in view of accuracy of a bonding device.

Further, an adjustment in height between a surface of a high-frequency functional element to be mounted and a surface of a dielectric substrate which is a primary mounting substrate is made so as to enable a length of a wire to be shortened. However, it is necessary to cut in a chip-mounting area on the primary mounting substrate, thereby leading to an increase in process cost.

Moreover, although a ribbon-type wire can be also used so as to reduce inductance at the connecting portion and prevent reflection, it is not preferable in view of reliable temperature change in practice.

In addition, although a flip-chip bonding using a through hole and the like can be also used so as to reduce inductance at the connecting portion and prevent reflection, it is not preferable in view of reliable temperature change in practice.

### SUMMARY OF THE INVENTION

Therefore, a first object of the present invention is to provide a high-frequency circuit for enabling reflection occurring at a connecting portion of a wire to be prevented. Further, a second object of the present invention is to provide, at low cost, a high-frequency circuit for enabling the reflection occurring at the connecting portion of the wire to be prevented with high accuracy and high reliability.

In order to solve the aforementioned problem, the present invention has the following features. The present invention is directed to a high-frequency circuit having a high-frequency functional element mounted on a dielectric substrate, which comprises: a first transmission line formed in the high-frequency functional element; a second transmission line formed on the dielectric substrate and having a characteristic impedance lower than or equal to 50Ω; a wire for connecting between the first transmission line and the second transmission line; a third transmission line connected to the second transmission line and having a characteristic impedance higher than 50Ω; a via hole section formed so as to pass through the dielectric substrate and having a top side conductive land connected to the third transmission line; and a fourth transmission line connected to a bottom side conductive land of the via hole section.

According to the above-described invention, an equivalent circuit of the whole circuit is a typical low pass filter of an LCLC structure in which a first series inductance generated due to parasitic inductance of a wire; a first shunt capacitance generated due to ground capacitance which occurs in the second transmission line portion; a second series inductance generated due to high impedance characteristic of the third transmission line; and a second shunt capacitance of ground capacity which occurs between the via hole section and the ground conductive area adjacent thereto are connected to each other. Unlike in the case of a prior art, the high-frequency circuit configuration of the present invention in which the whole circuit is configured as a filter circuit realizes high frequency characteristic of low reflection in a wide range of frequency band.

Further, the wire, the second transmission line, the third transmission line, the via hole section, and the fourth transmission line can be formed without using a particular wiring process. Therefore, a high-frequency circuit having low reflection in a wide band with high accuracy and high reliability can be provided at low cost.

Moreover, the ground conductive area is restrictively disposed adjacent to the via hole section so as not to ground the via hole section. Therefore, no ground conductive area is provided in an area which is opposite to the signal strip in the third transmission line and is on the bottom surface of the dielectric substrate, thereby enabling the characteristic impedance of the third transmission line to be set high. Therefore, an essential condition, for the typical low pass filter of the LCLC structure, that the second series inductance must be set high in a case where the first series inductance is high, can be easily realized.

Moreover, the inductance of the connecting through-via in the via hole section is added to the inductance of the third transmission line, thereby enabling a physical line length of the third transmission line to be shortened. Accordingly, an advantageous effect that a circuit area is downsized can be also achieved.

In a conventional high-frequency circuit, a matching circuit for matching parasitic inductance of the wire to 50Ω is configured so as to be further connected to the via hole section. Therefore, there was a high possibility that reflection occurs in a portion of design frequency bands in millimeter wave bands in which it is difficult to set each of the reflection of a signal generated in the matching circuit and the reflection of a signal generated in the via hole section so as to have a low intensity over a wide band. However, in the high-frequency circuit of the present invention, the whole circuit including the via hole section is formed as a matching circuit for building-out the parasitic inductance of the wire. Accordingly, a signal is transmitted with low reflection over a wide band.

Preferably, the fourth transmission line has a characteristic impedance higher than or equal to 50Ω in at least a portion of an area thereof.

In this configuration, an equivalent circuit of the whole circuit is a typical low pass filter of an LCLCL structure in which a first series inductance generated due to parasitic inductance of the wire; a first shunt capacitance generated due to ground capacitance which occurs at the second transmission line portion; a second series inductance generated due to high impedance characteristic of the third transmission line; a second shunt capacitance generated due to ground capacity which occurs between the via hole section and the ground conductive area adjacent thereto; and a third series inductance generated due to high impedance characteristic of the fourth transmission line are connected to each other. Unlike in the case of a prior art, the high-frequency circuit configuration of the present invention in which the whole circuit is configured as a filter circuit realizes the high frequency characteristic of low reflection in a wide range of frequency band.

Moreover, the ground conductive area is restrictively disposed adjacent to the via hole section so as not to ground the via hole section. Therefore, no ground conductive area is provided in an area which is opposite to the signal strip in the fourth transmission line and is on the top surface of the dielectric substrate, thereby enabling the characteristic impedance of the fourth transmission line to be easily set high. Therefore, an essential condition, for the typical low pass filter of the LCLCL structure, that the third series inductance must be set high in a case where the first series inductance is high, can be easily realized.

Preferably, the first transmission line has a characteristic impedance lower than or equal to 50Ω at a connecting portion between the wire and the first transmission line.

In this configuration, an equivalent circuit of the whole circuit is a typical low pass filter of a CLCLC structure in which a first shunt capacitance generated due to ground capacity at a connecting portion between the first transmission line and the wire; a first series inductance generated due to parasitic inductance of the wire; a second shunt capacitance generated due to ground capacity which occurs at the second transmission line portion; a second series inductance generated due to high impedance characteristic of the third transmission line; and a third shunt capacitance generated due to ground capacity which occurs between the via hole section and the ground conductive areas adjacent thereto are connected to each other. Unlike in the case of a prior art, the high-frequency circuit configuration of the present invention in which the whole circuit is configured as a filter circuit realizes the high frequency characteristic of low reflection in a wide range of frequency band.

Preferably, the first transmission line has a coplanar-type GSG pad at the connecting portion between the wire and the first transmission line.

Therefore, high frequency characteristic in a wafer state can be detected using a high frequency probe of an air coplanar shape.

Preferably, a ground conductive pad contained in the pad is adjacent to a signal strip in the first transmission line.

Therefore, a characteristic impedance of the first transmission line can be reduced in the wire connecting portion, thereby enabling the ground capacity to be effectively generated in a reduced area.

Preferably, toward an end portion of a signal strip in the first transmission line, a clearance between the signal strip and the ground conductive pad is narrower.

In this configuration, a ground capacity value required for the first transmission line in an area adjacent to the wire connecting portion is generated as well as a difference in impedance between the wire and a transmission line in the high-frequency functional element connected to the first transmission line can be reduced, thereby enabling unnecessary signal reflection to be suppressed and high frequency characteristic of reduced reflection to be obtained as the whole circuit.

Preferably, the second transmission line is a ground-added coplanar strip line.

This configuration enables variation in high-frequency circuit characteristic generated due to process variation to be more suppressed as compared to a case where the second transmission line is formed as a microstrip line. More specifically, it is necessary to enhance the high frequency grounding in the ground conductive area which is formed on the bottom surface of the high-frequency functional element in order to stably obtain high-frequency circuit characteristic. However, in a case where the second transmission line is formed as a microstrip line, the high frequency grounding is unstable due to variation in formation position of the grounding through-via which is formed by passing through the dielectric substrate, which is not preferable. On the other hand, the preferable configuration of the present invention enables the high frequency grounding to be stably maintained.

Preferably, the third transmission line comprises a signal strip connected to the top side conductive land, and a ground conductive area formed in areas other than areas opposite to the signal strip on the bottom surface of the dielectric substrate.

In this configuration, it is intended that a condition that the via hole section cannot be grounded is rather utilized to set a characteristic impedance of the third transmission line so as to have a high value which cannot be achieved by a typical circuit, thereby providing high inductance in the filter circuit configuration. In this configuration, a typical low pass filter of an LCLCL structure make it possible to easily realize a condition essential to a case where the third series inductance must be set high in the case of the first series inductance being high. This means that a band can be wider and reflection can be reduced as circuit characteristic.

Moreover, in the aforementioned configuration, a ground conductive area is eliminated from the vicinity of the via hole section, and therefore reduction in ground capacity generated between the top side conductive land and the ground conductive area can be intended. A ground capacitor which is inserted between inductances generated in the third transmission line and the connecting through-via appears to cause the characteristic impedance of the third transmission line to be reduced. As in the aforementioned configuration, however, the reduction in ground capacity occurring between the top side conductive land and the ground conductive area enables the characteristic impedance of the third transmission line to be kept high, resulting in further improving the characteristic of low reflection in a wide band.

Preferably, a dielectric constant of a dielectric composing the dielectric substrate is smaller than or equal to 5.

Therefore, if a strip width of the signal strip is set as about 100 micron which is a minimum value which is adopted in a standard wiring rule for a ceramic substrate or resin substrate, a characteristic impedance of the third transmission line can be set as, for example, 115Ω or higher.

Moreover, a dielectric constant of the dielectric substrate is set as 5 or less in the via hole section, thereby enabling reduction in ground capacity generated between the ground conductive area and the top side conductive land which are present in the vicinity of the via hole section. Therefore, the characteristic impedance of the third transmission line appears to increase, thereby enabling the characteristic of low reflection to be realized in a wide band.

Furthermore, when the dielectric constant of the substrate is reduced, the increase in phase quantity of a passing signal generated through transmission of a unit length is reduced, and therefore even when a low-cost process having low wiring accuracy and large error is used, the high-frequency circuit of the present invention can be manufactured at preferable yield.

Further, the reflection characteristic of the wire connecting portion substantially depends on a dielectric constant of the dielectric substrate to which the wire is connected as well as a shape of the wire. This is because ground capacity occurs, at a portion to which the wire is connected, between the portion and the bottom surface of the dielectric substrate. By controlling a strip width of the signal strip in the second transmission line at the portion to which the wire is connected, an optimal ground capacity value can be obtained in the low pass filter circuit, thereby enabling the characteristic of low reflection to be realized in a wide band. When a substrate of a high dielectric constant is used, however, even the ground capacity value generated at the portion to which the wire is connected becomes a larger value than the optimal ground capacity value, and optimal low pass filter characteristic cannot be obtained. On the other hand, in a case where a substrate of a low dielectric constant is used, an optimal capacity value that is large is applicable when a line length is increased, and the optimal capacity value that is small is also applicable. Accordingly, the dielectric constant of the substrate is preferably set low.

Preferably, a strip width of a signal strip in the third transmission line is smaller than a strip width of a signal strip in the second transmission line.

Therefore, the characteristic impedance of the third transmission line can be set high.

Preferably, the second transmission line has a characteristic impedance lower than or equal to 45Ω.

Preferably, the third transmission line has a characteristic impedance higher than or equal to 110Ω.

These and other objects, features, aspects, and advantages of the present invention will become more apparent from the following detailed description when taken in conjunction with the accompanying drawings.

### BRIEF DESCRIPTION OF THE DRAWINGS

FIG. 1A is a schematic cross-sectional view illustrating an example of a high-frequency circuit according to a first embodiment of the present invention;

FIG. 1B is a diagram illustrating a wiring pattern on a top surface of a dielectric substrate 1 shown in FIG. 1A;

FIG. 1C is a diagram illustrating a wiring pattern on an bottom surface of the dielectric substrate 1 shown in FIG. 1A;

FIG. 1D is a block diagram illustrating components of the high-frequency circuit according to the first embodiment of the present invention;

FIG. 2 is a diagram illustrating an analytical model of a ground-added coplanar strip line used for comparison simulation;

FIG. 3A is a Smith chart illustrating reflected impedance (S11) from 3 GHz to 75 GHz at the wire connecting portion for a microstrip line in the case of a signal strip 16 having a strip width of 1000 micron;

FIG. 3B is a Smith chart illustrating reflected impedance (S11) from 3 GHz to 75 GHz at the wire connecting portion for a ground-added coplanar strip line in the case of the signal strip 16 having a strip width of 600 micron;

FIG. 4 is a diagram for explaining a configuration principle of a building-out circuit in the case of parasitic inductance occurring at the wire portion, which is used in the high-frequency circuit of the present invention;

FIG. 5A is a top view illustrating an example of another configuration of a third transmission line 6;

FIG. 5B is a cross-sectional view illustrating an example of another configuration of the third transmission line 6;

FIG. 6A is a graph obtained when characteristic impedances of a microstrip line and the third transmission line 6 having the transmission line configuration as shown in FIGS. 5A and 5B are plotted against the strip widths of the signal strips;

FIG. 6B is a graph obtained when characteristic impedances of the third transmission line 6 having the transmission line configuration as shown in FIGS. 5A and 5B are plotted against a dielectric constant of the dielectric substrate;

FIG. 7A is a diagram illustrating an equivalent circuit of the wire connecting portion which is obtained by performing analysis based on a result of an analysis of electromagnetic field from 3 GHz to 81 GHz;

FIG. 7B is a diagram illustrating an equivalent circuit which is obtained by simplifying the equivalent circuit shown in FIG. 7A;

FIG. 7C is a diagram illustrating a result of electromagnetic field analysis of the reflected impedance (S11) as seen from a terminal on a second transmission line 4 side of an actual configuration of the wire connecting portion and the reflected impedance (S11) of the simplified equivalent circuit;

FIG. 7D is a diagram illustrating a connecting portion between a wire 5 and a signal strip 3a;

FIG. 7E is a diagram illustrating a connecting portion between the wire 5 and the signal strip 16;

FIG. 8A is a diagram illustrating an equivalent circuit of a circuit block including the third transmission line 6, a via hole section 10, and a fourth transmission line 11, which is obtained by performing analysis based on a result of an analysis of electromagnetic field from 3 GHz to 81 GHz;

FIG. 8B is a diagram illustrating an equivalent circuit obtained by simplifying the equivalent circuit shown in FIG. 8A;

FIG. 8C is a diagram illustrating a result of electromagnetic field analysis of the reflected impedance (S22) as seen from a terminal on a TRL3 side of an actual configuration of the via hole section 10 and the reflected impedance (S22) of the simplified equivalent circuit;

FIG. 9A is a diagram illustrating an equivalent circuit of the whole configuration of the high-frequency circuit according to the first embodiment of the present invention;

FIG. 9B is a diagram illustrating a low pass filter of a CLCL structure which is to be formed;

FIG. 10 is a diagram illustrating an equivalent circuit of a high-frequency circuit according to a second embodiment of the present invention;

FIG. 11 is a diagram illustrating an equivalent circuit of a high-frequency circuit according to a third embodiment of the present invention;

FIG. 12A is a diagram illustrating a structure of a GSG pad for detecting high frequency characteristic;

FIG. 12B is a diagram illustrating a structure of the GSG pad in which clearances between the signal strip 24 and the ground conductive areas 25a are narrowed toward an end portion of the signal strip 24;

FIG. 13 is a block diagram schematically illustrating a high-frequency circuit for evaluation which is used in a measurement for examples;

FIG. 14 is a diagram illustrating a comparison between reflection characteristic for a comparative example and reflection characteristic for the example 1 of the present invention;

FIG. 15 is a diagram illustrating a comparison between reflection characteristic for the comparative example and reflection characteristic for the example 3 of the present invention;

FIG. 16A is a cross-sectional view illustrating a configuration outline in the case of a conventional high frequency package being surface-mounted on an external circuit substrate;

FIG. 16B is a diagram illustrating a wiring pattern on a top surface of a dielectric substrate 1 shown in FIG. 16A; and

FIG. 16C is a diagram illustrating a wiring pattern on a bottom surface of the dielectric substrate 1 shown in FIG. 16A.

### DESCRIPTION OF THE PREFERRED EMBODIMENTS

Hereinafter, embodiments of the present invention will be described with reference to the drawings.

### First Embodiment

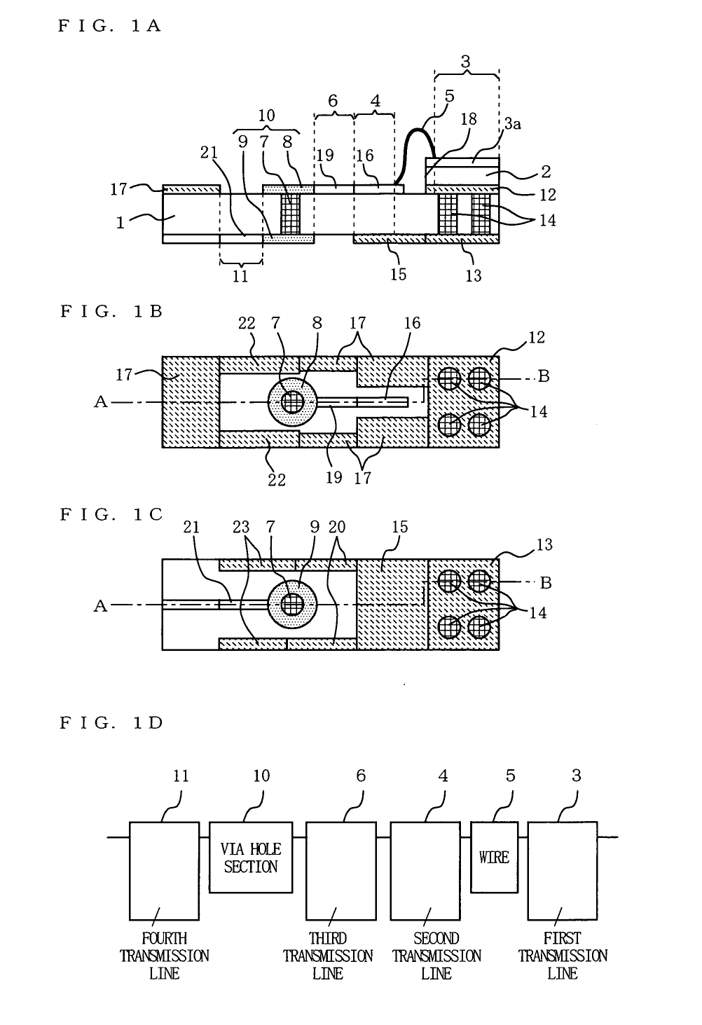

FIG. 1A is a schematic cross-sectional view illustrating an example of a high-frequency circuit according to a first embodiment of the present invention. FIG. 1B is a diagram illustrating a wiring pattern on a top surface of a dielectric substrate 1 shown in FIG. 1A. FIG. 1C is a diagram illustrating a wiring pattern on a bottom surface of the dielectric substrate 1 shown in FIG. 1A. FIG. 1D is a block diagram illustrating components of the high-frequency circuit according to the first embodiment of the present invention. FIG. 1A is also a cross-sectional view along lines AB of FIGS. 1B and C.

In FIGS. 1A to C, a high-frequency circuit according to the first embodiment comprises a dielectric substrate 1 and a high-frequency functional element 2. On a top surface of the dielectric substrate 1, ground conductive areas 12, 17, and 22, signal strips 16 and 19, and a top side conductive land 8 are formed. On a bottom surface of the dielectric substrate 1, ground conductive areas 13, 15, 20, and 23, a signal strip 21, and a bottom side conductive land 9 are formed. A connecting through-via 7 and a plurality of connecting through-vias 14 are formed from the top surface of the dielectric substrate 1 through the bottom surface thereof. The plurality of connecting through-vias 14 connect between the ground conductive area 13 and the ground conductive area 12. The high-frequency functional element 2 is mounted on the ground conductive area 12. A signal strip 3a is formed in the high-frequency functional element 2 (typically on the upper surface thereof). A bottom end of the connecting through-via 7 is connected to the signal strip 21 via the bottom side conductive land 9. The top end of the connecting through-via 7 is connected to one end of the signal strip 19 via the top side conductive land 8. The other end of the signal strip 19 is connected to one end of the signal strip 16. The other end of the signal strip 16 is connected to the signal strip 3a through a wire 5.

The dielectric substrate 1 is made of typical dielectric substrate material which is low-loss in a high frequency band. For the dielectric substrate 1, for example, ceramic material such as alumina or alumina nitride which is produced through high temperature sintering, glass-ceramic material which is produced through low temperature sintering, teflon (R), resin substrate material of a low dielectric constant such as liquid crystal polymer, can be used.

The high-frequency functional element 2 is a passive circuit such as an MMIC (monolithic microwave integrated circuit) having a substrate made of silicon, gallium arsenide, etc., or a filter circuit, or the like.

A first transmission line 3 is a transmission line which is formed in the high-frequency functional element 2. The first transmission line 3 is any of a coplanar strip line, a ground-added coplanar strip line, and a microstrip line. In FIGS. 1A to C, the first transmission line 3 is a ground-added coplanar strip line or a microstrip line. That is, the signal strip 3a and the ground conductive area 12 comprise a ground-added coplanar strip line or a microstrip line. The ground conductive area 12 is connected to the ground conductive area 13 through the connecting through-vias 14 so as to enhance high frequency grounding.

The second transmission line 4 is a transmission line which is connected to the first transmission line 3 through the wire 5. The second transmission line 4 is any of a coplanar strip line, a ground-added coplanar strip line, and a microstrip line. It is necessary to narrow clearances between the signal strip and the ground conductive areas formed on each side thereof so as to reduce a transmission line characteristic impedance generated in the coplanar strip line. However, there is a limit to the clearances being narrowed according to a standard wiring rule for a ceramic, a resin substrate and the like. Consequently, there is a limit to reduction in a transmission line characteristic impedance generated in the coplanar strip line. Therefore, the second transmission line 4 is more preferably a ground-added coplanar strip line or a microstrip line.

The characteristic impedance Z2 of the second transmission line 4 is lower than or equal to 50Ω. In a case where the characteristic impedance Z2 of the second transmission line 4 is lower than or equal to 50Ω, the second transmission line 4 functions as a ground capacitor in the circuit. Accordingly, the second transmission line 4 can compensate (building out) parasitic inductance produced by the wire 5, and specifically can improve reflection characteristic in a frequency band lower than 45 GHz band.

The second transmission line 4 is preferably a ground-added coplanar strip line rather than a mircostrip line. In a case where the second transmission line 4 is formed as a microstrip line, high frequency grounding for the ground conductive area 12 formed vertically below the high-frequency functional element 2 is supplied only from the ground conductive area 13 formed vertically below the ground conductive area 12. Therefore, variations in production of the plurality of connecting through-vias 14 connecting between the ground conductive area 12 and the ground conductive area 13 cause variations in reflected impedance characteristic of the wire connecting portion. However, in a case where the second transmission line 4 is formed as a ground-added coplanar strip line, high frequency grounding for the ground conductive area 12 is enhanced through the ground conductive areas 17 which are provided on both sides of the signal strip 16, thereby enabling the variation in reflected impedance characteristic to be reduced. Consequently, the second transmission line 4 is most preferably formed as a ground-added coplanar strip line. In FIGS. 1A to C, the second transmission line 4 is a ground-added coplanar strip line comprised of the signal strip 16, the ground conductive areas 17 and 15.

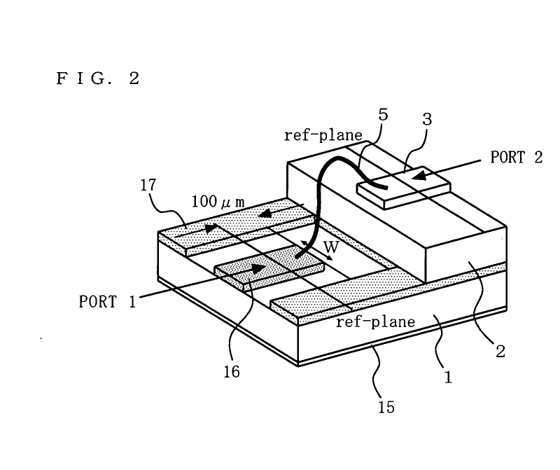

The inventor performed an electromagnetic field simulation in which reflected impedance (S11) in the case of the second transmission line 4 being a microstrip line is compared with reflected impedance (S11) in the case of the second transmission line 4 being a ground-added coplanar strip line. FIG. 2 is a diagram illustrating an analytical model for the ground-added coplanar strip line used for the comparison simulation. The microstrip line has the same analytical model except that the microstrip line is not provided with the ground conductive area 17 shown in FIG. 2, and the illustration is omitted. The inventor uses, as a port 1, the signal strip 16 in the ground-added coplanar strip line on the dielectric substrate 1 (a primary mounting substrate) made of liquid crystal polymer material having a thickness of 125 micron and a dielectric constant of 3. Further, a microstrip line of characteristic impedance 50Ω, which is formed on the gallium arsenide substrate having a thickness of 100 micron, is used as a port 2. Moreover, the port 1 is connected to the port 2 through the wire 5 having a diameter of 25 micron.

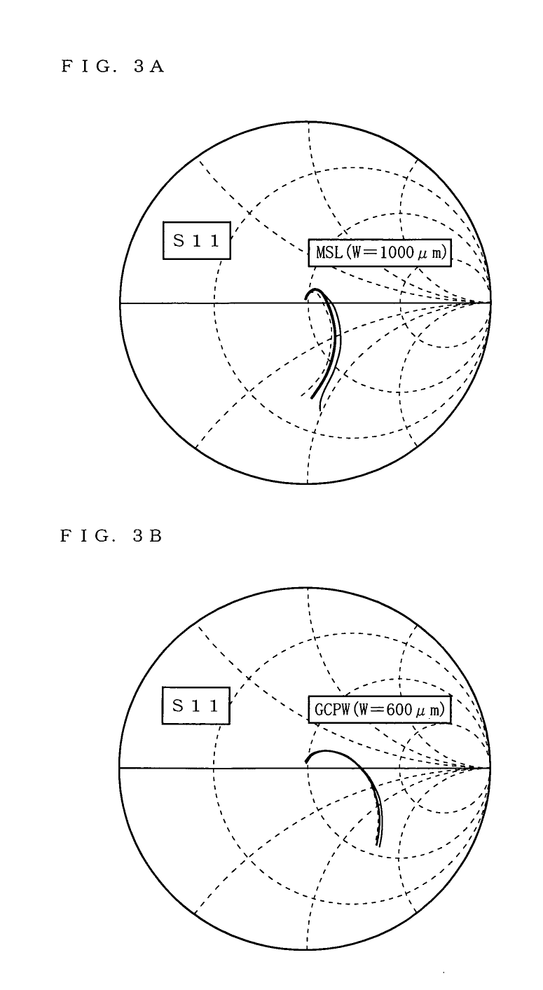

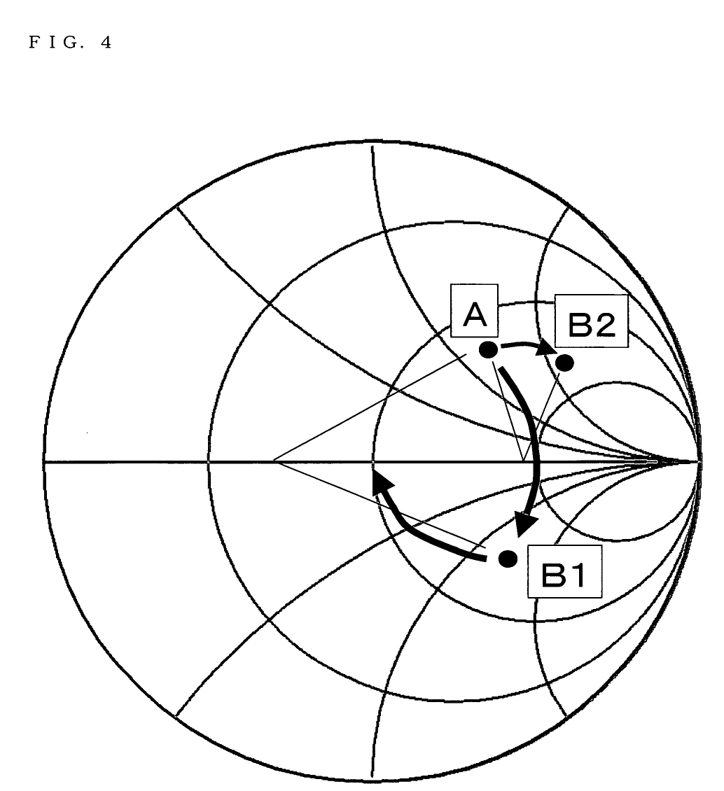

FIG. 3A is a Smith chart illustrating reflected impedance (S11) generated at from 3 GHz to 75 GHz at the wire connecting portion for the microstrip line in which a strip width of the signal strip 16 is set as 1000 micron based on the setting condition. FIG. 3B is a Smith chart illustrating reflected impedance (S11) generated at from 3 GHz to 75 GHz at the wire connecting portion for the ground-added coplanar strip line in which a strip width of the signal strip 16 is set as 600 micron based on the setting condition.

In each of FIGS. 3A and 3B, three kinds of data are shown. Among the three kinds of data, data indicated at the center by a medium-thick solid line is data which is obtained when the connecting through-via 14 which is closest to the wire connecting portion among the plurality of connecting through-vias 14 each having a diameter of 280 micron, disposed at 400 micron intervals, and formed vertically below the high-frequency functional element 2, is spaced apart from the end part 18 of the high-frequency functional element 2 by a distance of 300 micron. The data indicated on the left side of the chart by dotted lines is data which is obtained when the connecting through-via 14 is spaced apart from the end part 18 of the high-frequency functional element 2 by a distance of 350 micron. The data indicated on the right side of the chart by a thin solid line is data which is obtained when the connecting through-via 14 is spaced apart from the end part 18 of the high-frequency functional element 2 by a distance of 250 micron. That is, FIGS. 3A and 3B show variations in reflected impedance characteristic of the wire connecting portion, which are generated due to the variations in production of the connecting through-via 7 and the connecting through-vias 14. As can be seen from the comparison between FIG. 3A and FIG. 3B, it can be appreciated that the second transmission line 4 of a ground-added coplanar strip line is more effective than the second transmission line 4 of a microstrip line in view of restriction of the variations in reflection phase characteristic.

A configuration principle of a building-out circuit used in the high-frequency circuit of the present invention in the case of parasitic inductance occurring at the wire portion will be described with reference to drawings called Smith charts. In the Smith chart, the center thereof indicates impedance 50Ω, which is a state of the least reflection. It is indicated that the larger a distance from the center of the chart is, the higher a reflection intensity is. A matching circuit must be designed in a circuit having reflection so as to move the reflected impedance characteristic to the center of the chart. Here, in FIG. 4, typical reflected impedance characteristic for the wire portion at a predetermined frequency appears at a point A. Here, when a transmission line having a characteristic impedance lower than 50Ω is connected to the wire portion, the point A moves to a point B1. On the other hand, when a transmission line having a characteristic impedance higher than 50Ω is connected to the wire portion, the point A moves to a point B2. As can been seen from this example, a characteristic impedance of a transmission line controls a position of a rotation center for rotating reflected impedance in the Smith chart. When a transmission line having impedance lower than 50Ω is connected, the position of the rotation center is to the left of the center of the chart. When a transmission line having impedance higher than 50Ω is connected, the position of the rotation center is to the right of the center of the chart. The direction of the rotation is always a clockwise direction. Further, an angle of the rotation is twice an electric length of a transmission line, and proportional to a frequency.

The high-frequency circuit according to the present invention adopts a method in which, in order to move, to 50Ω, the reflected impedance point A for the wire portion, the second transmission line is initially set so as to have a characteristic impedance lower than or equal to 50Ω, thereby to move the reflected impedance point to a point B, and further the third transmission line is set so as to have a value greater than 50Ω, thereby to move the reflected impedance point to the center of the chart.

The electric length of the second transmission line 4 is smaller than or equal to 90 degrees, preferably smaller than or equal to 45 degrees, and more preferably smaller than or equal to 30 degrees, at an upper limited frequency in a design band. When reflected impedance characteristics generated due to parasitic inductance of the wire 5 are plotted (point A) in the Smith chart, the reflected impedance characteristic point is positioned in the first quadrant in the Smith chart. More specifically, the reflected impedance characteristic point tends to be in a direction of 90 degrees in a low frequency band and tends to be in a direction in which the phase angle is reduced in a high frequency band. In the high-frequency circuit of the present invention in which the reflected impedance characteristic point is moved to the point B by the second transmission line and thereafter the reflected impedance characteristic point is moved to the center of the chart by the third transmission line having impedance higher than 50Ω, the point B must be positioned in the fourth quadrant in the chart. Accordingly, a maximum value of the moving rotation angle between the point A and the point B is 180 degrees, and a maximum value of the electric length of the second transmission line is set as 90 degrees as a principle.

Moreover, as described above, at an upper limited frequency in the design band, a phase condition of the reflected impedance of the wire is smaller than 90 degrees, so that the reflected impedance characteristic point is positioned at positive 45 degrees or smaller. Further, considering a range in which the reflected impedance characteristic point can be moved to the center of the chart by the third transmission line of high impedance, it can be appreciated that the point B is preferably positioned at approximately negative 45 degrees at an upper limited frequency in a design band. Based on these conditions, the second transmission line acts so as to move the reflected impedance from the point A to the point B by an angle smaller than or equal to 90 degrees and an electric length of the transmission line is preferably set as 45 degrees or smaller.

Further, specifically, for example, in a case where used is a ground-added coplanar strip line in which the design band contains a high frequency band of about 60 GHz, the wire 5 has a diameter of 25 micron, the wire 5 has a length of 350 micron, the dielectric substrate has a dielectric constant of 3, the dielectric substrate 1 has a substrate thickness of 125 micron, and the second transmission line 4 has the signal strip 16 spaced apart from each of the ground conductive areas 17 on both sides thereof by a distance of 100 micron, the inventor ascertained that the phase of the reflected impedance of the wire 5 is rotated up to about 0 degree at 60 GHz. The inventor ascertained that a larger rotation of the phase occurs in a higher frequency band as compared to the above case, and the phase of the reflected impedance is smaller than 0 degree. Even if an electric length is designed so as to be slightly increased at the upper limited frequency in the design band in order to realize wide band characteristic, the rotation angle obtained by the second transmission line 4 is more preferably set so as to be smaller than or equal to 60 degrees at the upper limited frequency in the design band in order to obtain an advantageous characteristic in the high-frequency circuit of the present invention. Accordingly, it is particularly preferable that the electric length of the second transmission line is set so as to be smaller than or equal to 30 degrees at the upper limited frequency in the design band.

Moreover, it is necessary to set the characteristic impedance of the second transmission line 4 lower than or equal to 50Ω, more preferably lower than 50Ω. It is because when a transmission line having impedance higher than 50Ω is connected, it leads to increase in reflection intensity occurring at the wire. More preferably, a value which is much lower than 50Ω should be selected. However, a line of low impedance requires a wide circuit area to be occupied. Moreover, in a case where a strip width of the signal strip 16 is greatly increased, a high order mode occurs between the signal strip 16 and the ground conductive area 15 formed opposite thereto on the back surface of the dielectric substrate 1 interposed therebetween. For the limitation for controlling these states, the characteristic impedance of the second transmission line 4 is generally set as a value greater than or equal to 20Ω.

For the connection through the wire 5, wedge bonding for which a conductor of gold or the like is used or a typical wire connecting technique such as ball bonding may be used, or, needless to say, a connecting technique in which a wire is formed as a ribbon-type conductor may be used in order to achieve reduction in inductance. In addition, needless to say, the surface of the dielectric substrate 1 is cut in the area in which the high-frequency functional element 2 is disposed, and the high-frequency functional element 2 is embedded in the cut and thereby a difference in height is reduced between the surface of the dielectric substrate 1 and the surface of the high-frequency functional element 2 to shorten a length of the wire 5 for connecting between the first transmission lines 3 and the second transmission line 4, and thereby the inductance of the wire 5 may be reduced.

Moreover, in the above-described configuration, a high-frequency circuit in the case of the number of connections through the wire 5 being one is described. However, the number of connections through the wire 5 may be plural. When the number of connections is set as plural, an equivalent circuit in which a plurality of parasitic inductance circuits for the wire portion are aligned in parallel is obtained, thereby transparently reducing parasitic inductance, as compared to a case where the number of connections is one. Also in this case, it is possible to obtain an advantageous effect using the aforementioned circuit configuration and setting conditions.

Next, the third transmission line 6 as a feature of the present invention will be described. The third transmission line 6 connects between the second transmission line 4 and the via hole section 10. In FIGS. 1A to C, the third transmission line 6 includes the signal strip 19 and the ground conductive areas 17 and 20. The signal strip 19 is formed on the top surface of the dielectric substrate 1. One end of the signal strip 19 is connected to one end of the signal strip 16. The other end of the signal strip 19 is connected to the top side conductive land 8. The ground conductive area 17 formed on the top surface of the dielectric substrate 1 and the ground conductive area 20 formed on the bottom surface thereof are not disposed adjacent to the top side conductive land 8 and the bottom side conductive land 9 so as not to ground them, respectively.

Thus, the ground conductive areas 17 and 20 are far from the vicinity of the signal strip 19, and thereby a high characteristic impedance, for example, a characteristic impedance having a value greater than or equal to 100Ω can be obtained in the third transmission line 6 including the signal strip 19 and the ground conductive areas 17 and 20.

The third transmission line in the high-frequency circuit of the present invention acts so as to move, to the center of the chart, reflected impedance characteristic positioned in the fourth quadrant in the Smith chart. From this, the characteristic impedance of the third transmission line is preferably set high. The higher characteristic impedance the connected transmission line has, the further rightward the rotation center point can be set from the center in the Smith chart when reflected impedance is rotated and moved in the clockwise direction. This means that as the characteristic impedance of the third transmission line can be set higher in the high-frequency circuit of the present invention, a circuit having reflection characteristic of high intensity can be matched so as to have less reflection. Moreover, the higher the characteristic impedance of the third transmission line can be set in the high-frequency circuit of the present invention, the more allowance the matching circuit can be designed to have, thereby enabling a frequency band in which a non-reflection matching condition can be obtained to be widen into a wide band.

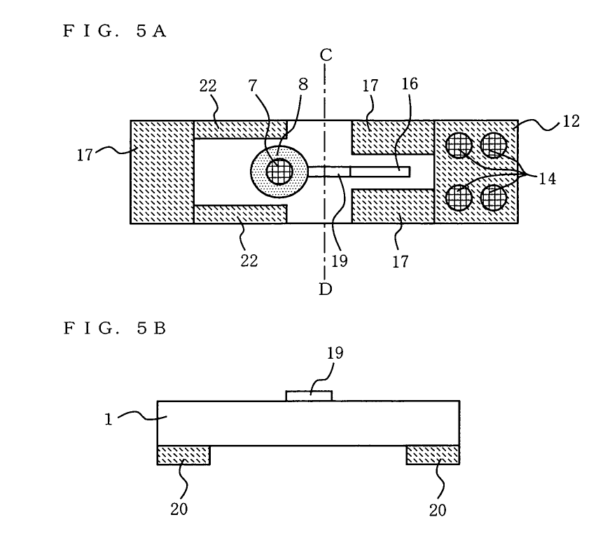

FIGS. 5A and 5B are diagrams illustrating an example of another configuration of the third transmission line 6. FIG. 5A is a diagram illustrating a top surface of the dielectric substrate 1. FIG. 5B is a cross-sectional view of the dielectric substrate 1 along the lines CD. As shown in FIGS. 5A and 5B, while no ground conductive areas are provided on either side of the signal strip 19 on the top surface of the dielectric substrate 1, the ground conductive areas 20 may be provided only on the bottom surface of the dielectric substrate 1. Thus, by eliminating the ground conductive areas adjacent to the signal strip 19, the characteristic impedance of the third transmission line 6 becomes higher, thereby enabling the low reflection matching characteristic to be realized in a wider band. As described above, the third transmission line 6 preferably has a transmission line structure which includes the signal strip 19 connected to the top side conductive land 8 and the ground conductive areas 20 formed on the bottom surface of the dielectric substrate 1 in an area other than the area opposite to the signal strip 19.

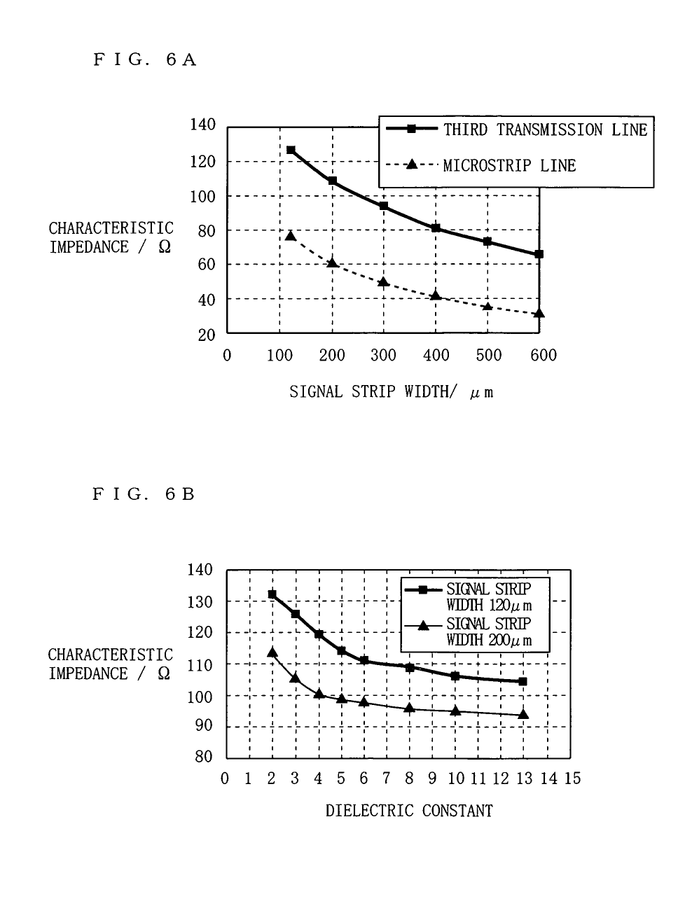

FIG. 6A is a graph which is obtained when the respective characteristic impedances of a microstrip line and the third transmission line 6 having a transmission line structure as shown in FIG. 5A and FIG. 5B are plotted against a strip width of the signal strip. The third transmission line 6 used here has a transmission line structure in which the signal strip is formed on the top surface of the dielectric substrate 1 made of liquid crystal polymer material having a dielectric constant of 3 and a thickness of 125 micron, and the ground conductive areas 20 are formed on the bottom surface thereof, the ground conductive areas 20 being spaced apart from each other by 1000 micron. Further, the microstrip line used here has a typical microstrip line structure in which a signal strip is formed on the top surface of the similar dielectric substrate and the ground strip is formed beneath the bottom surface thereof.

As can be seen in FIG. 6A, while the typical microstrip line has a characteristic impedance lower than 80Ω even when the width of the signal strip is reduced to 120 micron, the third transmission line 6 of the present invention has a characteristic impedance increased to approximately 130Ω when the width of the signal strip is reduced to 120 micron. As seen from another standpoint, it can be understood that the strip width of the signal strip 19 is preferably thinner than the strip width of the signal strip 16.

FIG. 6B is a graph which is obtained when the characteristic impedances of the third transmission line 6 having a transmission line structure as shown in FIG. 5A and FIG. 5B are plotted against a dielectric constant of the dielectric substrate. The third transmission line 6 used here has a transmission line structure in which the signal strip is formed on the top surface of the dielectric substrate 1 having a thickness of 125 micron, and the ground conductive areas 20 are formed on the bottom surface thereof, the ground conductive areas 20 being spaced apart from each other by 1000 micron. In FIG. 6B, the respective characteristic impedances in the case of a width of the signal strip being 120 micron and in the case of the width thereof being 200 micron are plotted.

As can be seen in FIB. 6B, the lower the dielectric constant of the dielectric substrate 1 is, the higher the characteristic impedance can be made. This is because the lower the dielectric constant is, the lower the capacity between the signal strip 19 and the ground conductive areas 20 on the bottom surface of the substrate is, thereby increasing the characteristic impedance. Specifically, in a case where the dielectric constant is smaller than or equal to 5, the characteristic impedance becomes high, and therefore a material having a dielectric constant which is smaller than or equal to 5 is preferably used for the dielectric substrate 1.

The via hole section 10 includes the connecting through-via 7, the top side conductive land 8, and the bottom side conductive land 9. The via hole section 10 connects between the third transmission line 6 and the fourth transmission line 11.

The fourth transmission line 11 includes the signal strip 21, and the ground conductive areas 22 and 23. The signal strip 21 is formed on the bottom surface of the dielectric substrate 1. One end of the signal strip 21 is connected to the bottom side conductive land 9.

Hereinafter, a configuration in which reflection occurring at the wire portion is reduced and an effect thereof according to the embodiment of the present invention will be described based on a principle of the reflection being reduced.

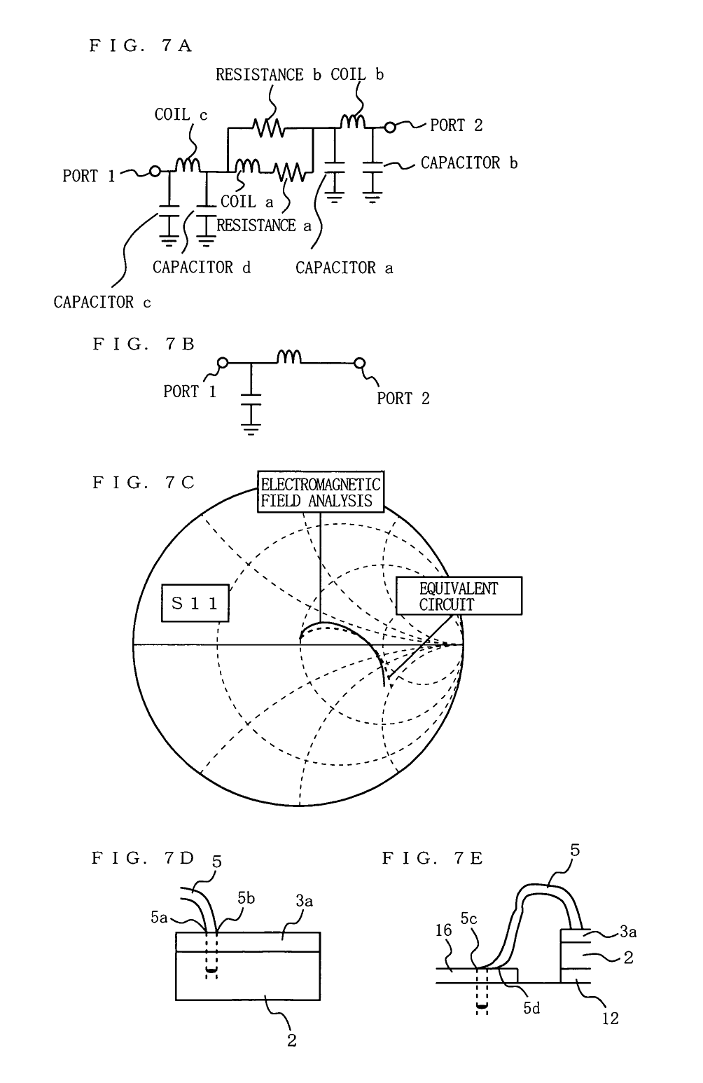

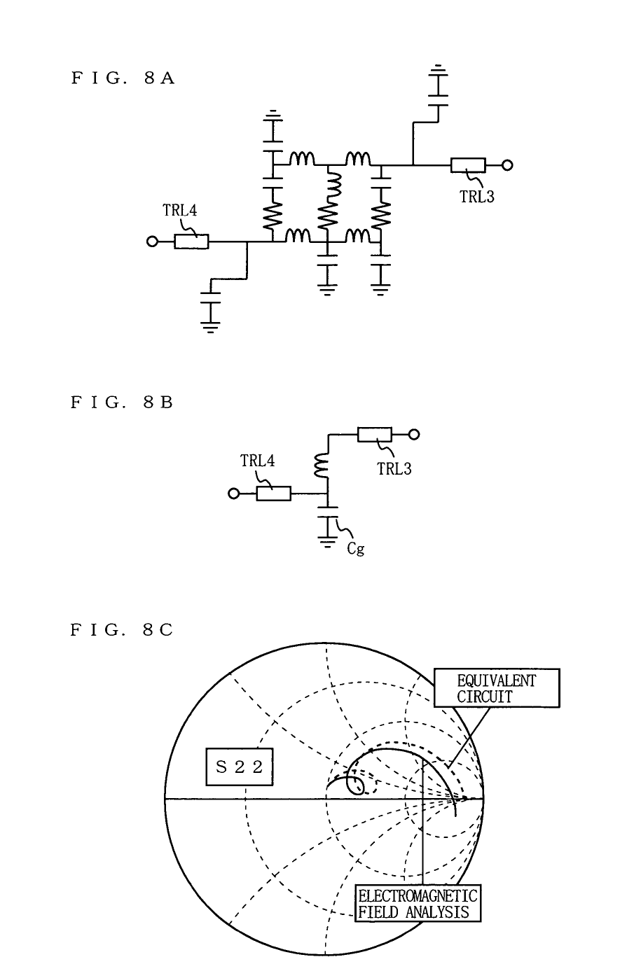

FIG. 7A is a diagram illustrating an equivalent circuit for the wire connecting portion, which is obtained by making an analysis based on a result of an electromagnetic field analysis from 3 GHz to 81 GHz. In FIG. 7A, a coil a is an inductance generated in the wire 5. A coil b is an inductance which may be generated between the left end 5a and the right end 5b of the wire 5 at the connecting portion between the wire 5 and the signal strip 3a shown in FIG. 7D. A coil c is an inductance which may be generated between the left end 5c and the right end 5d of the wire 5 at the connecting portion between the wire 5 and the signal strip 16 in the second transmission line 4 shown in FIG. 7E. A resistance a is a resistance of the wire 5. A resistance b is a radiation resistance indicating energy loss of electromagnetic wave which is leaked from the wire 5. A capacitor a is a capacitor which occurs between the first transmission line 3 and the ground conductive area 12 (specifically, between the ground conductive area 12 and the first transmission line 3 lying on the left side from the left end 5a of the wire 5 at the connecting portion between the wire 5 and the first transmission line 3). A capacitor b is a capacitor which occurs between the first transmission line 3 and the ground conductive area 12 (specifically, between the ground conductive area 12 and the first transmission line 3 lying on the right side from the right end 5b of the wire 5 at the connecting portion between the wire 5 and the first transmission line 3). A capacitor c is a capacitor which occurs between the signal strip 16 and the ground conductive area 17 of the second transmission line 4 (specifically, between the ground conductive area 17 and the second transmission line 4 lying on the left side from the left end 5c of the wire 5 at the connecting portion between the wire 5 and the second transmission line 4). A capacitor d is a capacitor which occurs between the signal strip 16 and the ground conductive area 17 of the second transmission line 4 (specifically, between the ground conductive area 17 and the second transmission line 4 lying on the right side from the right end 5d of the wire 5 at the connecting portion between the wire 5 and the second transmission line 4). The respective settings for a port in an analytical model, a transmission line, a wire and the like are the same as that shown in FIG. 2. As shown in FIG. 7A, an equivalent circuit for the wire connecting portion is a complicated circuit which includes inductance of the portion connecting to the first transmission line 3, inductance of the portion connecting to the second transmission line 4, a ground capacitor, a conductive resistance at the wire portion, radiation resistance at the wire portion, and the like, in addition to parasitic inductance of the wire.

FIG. 7B is a diagram illustrating an equivalent circuit obtained by simplifying the equivalent circuit shown in FIG. 7A. As shown in FIG. 7B, the equivalent circuit is simplified as a circuit including only parasitic inductance of the wire and ground capacitor at the connecting portion between the second transmission line 4 and the wire. FIG. 7C is a chart illustrating a result of electromagnetic field analysis of reflected impedance (S11) as seen from a terminal on the second transmission line 4 side of an actual configuration of the wire connecting portion, and reflected impedance (S11) of the simplified equivalent circuit. As shown in FIG. 7C, it can be appreciated that the simplified equivalent circuit provides a good modeling of high frequency characteristic of the actual configuration over an extremely wide band from 3 GHz to 81 GHz. Therefore, in the following discussion, the wire connecting portion can be represented and simplified as the equivalent circuit shown in FIG. 7B.

FIG. 8A is a diagram illustrating an equivalent circuit of a circuit block which includes the third transmission line 6, the via hole section 10, and the fourth transmission line 11, the equivalent circuit being obtained by making an analysis based on a result of analysis of the electromagnetic field from 3 GHz to 81 GHz. The equivalent circuit shown in FIG. 8A is a complicated circuit which includes ground capacities which occur between the top side conductive land 8 and the adjacent ground strips, ground capacities which occur between the bottom side conductive land 9 and the adjacent ground strips, a capacity indicating a capacitive combination between the top side conductive land 8 and the conductive land 9, each inductance at the strip, each resistance which indicates strip loss, and each resistance which indicates dielectric loss, in addition to inductance of the connecting through-via, as with the equivalent circuit shown in FIG. 7A. The distributed constant lines TRL 3 and TRL 4 correspond to the third transmission line 6 and the fourth transmission line 11.

FIG. 8B is a diagram illustrating an equivalent circuit which is obtained by simplifying the equivalent circuit shown in FIG. 8A. As shown in FIG. 8B, the equivalent circuit is simplified as a circuit in which the inductance of the connecting through-via section (via hole section 10) and a ground capacitor Cg are provided between the distributed constant line TRL4 and the distributed constant line TRL3. FIG. 8C is a diagram illustrating a result of electromagnetic field analysis of the reflected impedance (S22) as seen from a terminal on the TRL3 side of the actual configuration of the via hole section 10, and reflection impedance (S22) of the simplified equivalent circuit. As shown in FIG. 8C, in the simplified equivalent circuit, the tendency of high frequency characteristic of the actual configuration is successively represented over an extremely wide band from 3 GHz to 81 GHz. Accordingly, in the following discussion, the circuit block including the third transmission line 6, the via hole section 10, and the fourth transmission line 11 can be represented and simplified as the equivalent circuit shown in FIG. 8B.

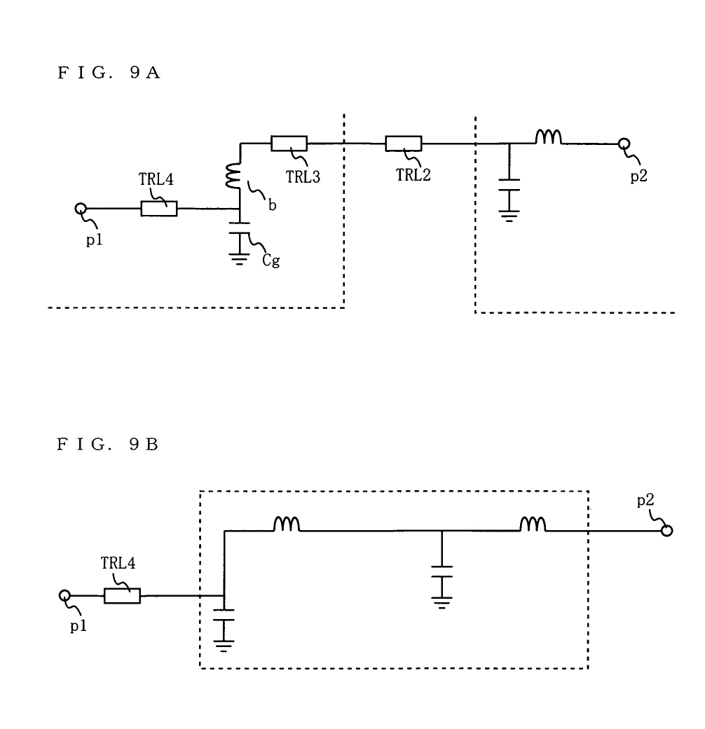

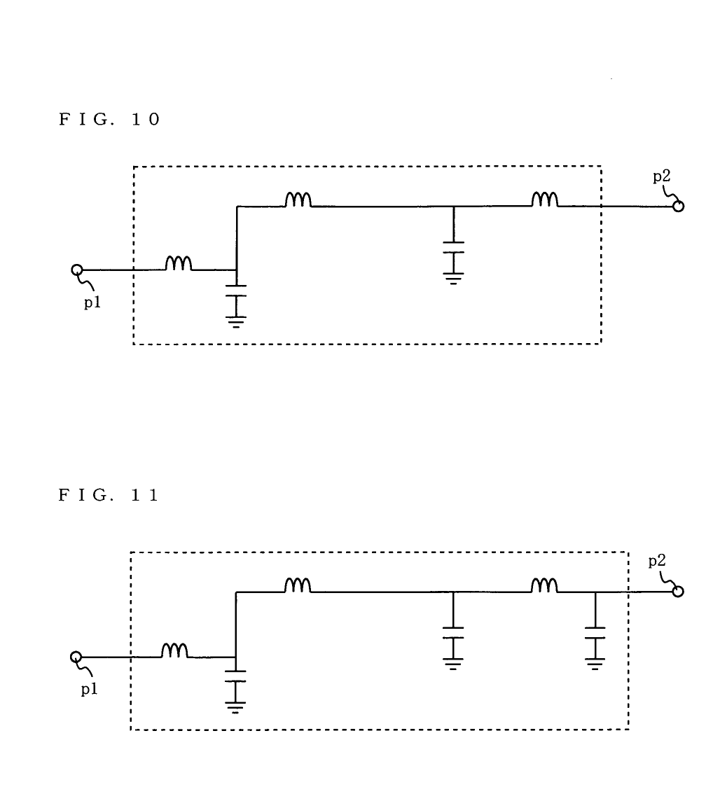

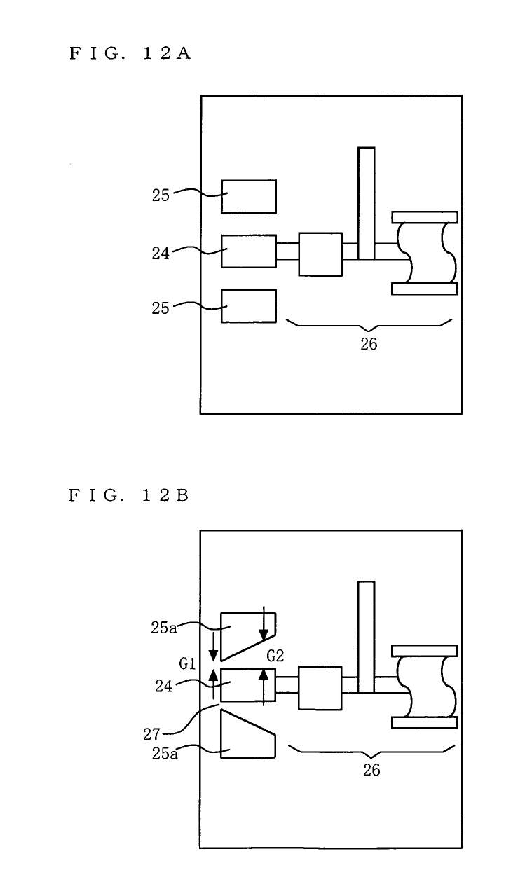

FIG. 9A is a diagram illustrating an equivalent circuit as the whole configuration of the high-frequency circuit according to the first embodiment of the present invention, which is configured based on the aforementioned discussion. The equivalent circuit shown in FIG. 9A is a high-frequency circuit in which the equivalent circuit for the wire connecting portion is disposed on the terminal p2 side, and the equivalent circuit for the fourth transmission line (TRL4) 11, the via hole section 10 (the coil b in FIG. 9A), and the third transmission line (TRL3) 6 is disposed on the terminal p1 side, and the second transmission line (TRL2) 4 is disposed between both equivalent circuits. Here, the characteristic impedance of the second transmission line 4 is set low, and the characteristic impedance of the third transmission line 6 is set high, which corresponds to formation of a “typical” low pass filter of CLCL structure (C: capacitor and L: inductance) as shown in FIG. 9B. An optimal design parameter required for the typical low pass filter characteristic is realized in the high-frequency circuit configuration of the present invention, thereby enabling the high-frequency circuit of low reflection to be realized in a wide band.

Here, in the high-frequency circuit of the present invention, inductance generated in the connecting through-via 7 at the via hole section 10 can be added to inductance generated due to high impedance characteristic of the third transmission line 6. Therefore, a line length of the third transmission line which is required to realize an optimal inductance which is required to realize the typical low pass filter characteristic can be reduced by an amount corresponding to the inductance, and therefore there is an advantage that efficiency of the area occupied by the circuit can be easily improved.

The inventor uses the equivalent circuit shown in FIG. 9A to check for an optimal circuit parameter for obtaining matching between the parasitic inductance of the wire 5 and each transmission line, taking, as an example, characteristics of the wire connecting portions described above. A ground-added coplanar strip line having a line width of 600 micron is used as the second transmission line 4 to analyze the electromagnetic field.

The inventor estimated a value of the circuit parameter aiming at obtaining a reflection intensity of minus 15 dB or higher in a band from 30 GHz to 65 GHz in the equivalent circuit shown in FIG. 9A. The second transmission line 4 (TRL2) had a characteristic impedance of 33Ω and an electric length of 12.5 degrees. The third transmission line 6 (TRL3) had a characteristic impedance of 120Ω and an electric length of 15.8 degrees. The ground capacitor Cg was 0.045fF. In a case where the aforementioned optimal parameter was set, a favorable reflection characteristic of minus 15 dB or less was able to be obtained in a frequency band from 38 GHz to 64 GHz. Here, the electric length of each transmission line is a value at 50 GHz. It was clear that a value to be taken by the characteristic impedance of the third transmission line 6 (TRL3) for matching in a circuit having a high inductance of the wire must be a great value.

As shown in FIG. 6A, it can be appreciated that it is effective that the signal strip 19 has a narrower strip width than the signal strip 16 so as to increase the characteristic impedance of the third transmission line 6 (TRL3). Further, as shown in FIG. 6B, it can be appreciated that it is effective that the dielectric substrate 1 has a dielectric constant smaller than or equal to 5 in order to increase the characteristic impedance of the third transmission line 6 (TRL3).

In a case where the high-frequency functional element 2 is connected to the via hole section 10, no ground conductive area is provided in the vicinity of the via hole section 10 so as not to ground the via hole section 10. Therefore, the ground strip is inevitably spaced apart from the vicinity of the signal strip in the third transmission line 6, and therefore the characteristic impedance of the third transmission line 6 can be easily set high. Consequently, the characteristic impedance of the third transmission line 6 becomes high. According to the present invention, the characteristic impedance of the third transmission line 6 inevitably becoming high is well utilized to provide matching between the wire connecting portion and the respective transmission lines. Therefore, the reflection generated at the wire connecting portion can be prevented without changing a standard wiring rule. Consequently, a high-frequency circuit which can prevent the reflection generated at the connecting portions of the wire with high accuracy and high reliability can be provided at low cost.

### Second Embodiment

Next, a high-frequency circuit according to a second embodiment of the present invention will be described. Components of the high-frequency circuit according to the second embodiment are the same as those for the first embodiment, and therefore FIG. 1A to D are also used here. The second embodiment is different from the first embodiment in that in at least a portion of the area of the fourth transmission line 11, the characteristic impedance is set so as to be higher than 50Ω in the second embodiment.

FIG. 10 is a diagram illustrating an equivalent circuit of a high-frequency circuit according to the second embodiment of the present invention. FIG. 10 shows a circuit configuration which is equivalent to a low pass filter of an LCLCL structure, the circuit configuration being obtained by adding, to the filter-type equivalent circuit of the CLCL structure according to the first embodiment shown in FIG. 9B, the fourth transmission line 11 (TRL4) which is set so as to have a high impedance. Thereby, the characteristic of low reflection can be realized over a wider band.

The fourth transmission line 11 includes the signal strip 21 formed on the bottom surface of the dielectric substrate 1, the ground conductive areas 23 formed on the bottom surface of the dielectric substrate 1, and the ground conductive areas 22 formed on the top surface of the dielectric substrate 1. The ground conductive areas 23 are formed so as to be spaced apart from the both sides of the signal strip 21, respectively. The ground conductive areas 22 are formed so as to be in no contact with the top side conductive land 8 and so as not to be provided in the area opposite to the signal strip 21.

The characteristic impedance of the fourth transmission line 11 is preferably set so as to be higher than 50Ω. The via hole section 10 is not grounded, and thereby no ground conductive area is formed adjacent to the fourth transmission line 11 as in the case of the third transmission line 6. Accordingly, it is possible to easily set the characteristic impedance of the fourth transmission line 11 so as to be higher than that of a transmission line of a typical configuration.

The inventor estimated a circuit parameter aiming at obtaining a reflection intensity of minus 15 dB or lower in a band from 30 GHz to 65 GHz in the equivalent circuit shown in FIG. 10. The second transmission line 4 (TRL2) had a characteristic impedance of 28Ω and an electric length of 15.2 degrees. The third transmission line 6 (TRL3) had a characteristic impedance of 120Ω and an electric length of 19.4 degrees. A ground capacitor was 0.051fF. The fourth transmission line 11 (TRL4) had a characteristic impedance of 90Ω and an electric length of 18.2 degrees. In a case where the aforementioned optimal parameter was set, a favorable reflection intensity of minus 15 dB or lower was able to be obtained in a frequency band from 34 GHz to 68 GHz. Here, the electric length of each transmission line is a value at a frequency of 50 GHz. It was clear that a value to be taken by the characteristic impedance of the fourth transmission line 11 for matching in a circuit having high inductance of the wire, must be a very great value.

In a case where the high-frequency functional element 2 is connected to the via hole section 10, since the via hole section 10 cannot be grounded, no ground conductive area is provided in the vicinity of the via hole section 10. Therefore, the characteristic impedance of the fourth transmission line 11 inevitably becomes high. According to the present invention, the characteristic impedance of the fourth transmission line 11 inevitably becoming high is well utilized so as to take matching between the wire connecting portion and the respective transmission lines. Therefore, reflection generated at the wire connecting portion can be prevented without changing a standard wiring rule. Consequently, a high-frequency circuit which can prevent the reflection generated at the connecting portion of the wire with high accuracy and high reliability can be provided at low cost.

In the above description, the equivalent circuit is modeled such that the ground capacity generated in the via hole section 10 is indicated by a capacitor of one lumped constant. However, it is also possible to handle the ground capacity as a transmission line which has a distributed constant and is set so as to have impedance lower than the third transmission line 6. In either case, in a case where the ground capacity required in the circuit design cannot be obtained in the conductive land of a shape which is defined by the wiring rule, the shape of the conductive land can be arbitrarily changed and adjusted so as to obtain a desired ground capacity.

In this case, the bottom side conductive land 9 is preferably wired so as to increase the ground capacity between the bottom side conductive land 9 and the ground conductive areas close thereto at a portion which is connected to the fourth transmission line 11. This is because while the present invention has an advantage that the inductance generated in the connecting through-via 7 is added to the inductance of the third transmission line 6, thereby enabling a characteristic of high performance and reduction in circuit volume to be simultaneously achieved, increase in ground capacity at the top side conductive land 8 disposed in between both circuits corresponds to reduction in characteristic impedance of the third transmission line 6, which is not preferable for maintaining the characteristic of the high-frequency circuit of the present invention.

Further, extension of the bottom side conductive land 9 into the area which is on the bottom surface of the dielectric substrate 1 and opposite to the signal strip 19 leads to reduction of the characteristic impedance of the third transmission line 6, which is not preferable for maintaining the characteristic of the high-frequency circuit of the present invention.

Accordingly, in a preferable example for the present invention where the fourth transmission line 11 of the present invention is set so as to have high impedance, thereby obtaining an advantageous effect, even when the characteristic impedance of the fourth transmission line 11 is set so as to be reduced by an arbitral distance in the vicinity of a connecting portion between the fourth transmission line 11 and the bottom side conductive land 9, it does not depart from the claims of the present invention.

### Third Embodiment

Next, a high-frequency circuit according to a third embodiment of the present invention will be described. Components of the high-frequency circuit according to the third embodiment are the same as those for the first embodiment, and therefore FIGS. 1A to D are also used here. The third embodiment is different from the first and second embodiments in that a characteristic impedance of the first transmission line 3 is set so as to be lower than 50Ω at a portion to which the wire is connected in the third embodiment.

FIG. 11 is a diagram illustrating an equivalent circuit of a high-frequency circuit according to the third embodiment of the present invention. FIG. 11 shows a circuit configuration which is equivalent to a low pass filter of an LCLCLC structure, the circuit configuration being obtained by adding, to the filter-type equivalent circuit of the LCLCL structure according to the second embodiment shown in FIG. 10, a wire connecting portion of the first transmission line 4 which is set so as to have low impedance. Thereby, the characteristic of low reflection can be realized over a wider band.

The inventor estimated a circuit parameter aiming at obtaining a reflection intensity of minus 15 dB or higher in a band from 30 GHz to 65 GHz in the equivalent circuit shown in FIG. 11. The second transmission line 4 (TRL2) had a characteristic impedance of 28Ω and an electric length of 17.2 degrees. The third transmission line 6 (TRL3) had a characteristic impedance of 120Ω and an electric length of 19.4 degrees. A ground capacitor Cg was 0.051fF. The characteristic impedance was set as 33Ω in an area in which the length from the connecting portion between the first transmission line 3 and the wire 5 is up to 80 micron. In this case, favorable reflection characteristic of minus 15 dB or more was able to be obtained in a band from 40 GHz to 64 GHz. Here, the electric length is a value at 50 GHz.

In order to reduce the characteristic impedance in the line end of the first transmission line 3, a GSG pad can be used for detecting a high frequency characteristic using a high frequency coplanar type probe in an on-wafer state. FIG. 12A is a diagram illustrating a structure of the GSG pad for detecting a high frequency characteristic. As shown in FIG. 12A, the GSG pad includes a signal strip 24 disposed at the line end of the first transmission line 3, and ground conductive areas 25 which are spaced apart from both sides of the signal strip 24 by arbitral clearance, respectively. The ground conductive areas 25 are disposed adjacent to the signal strip 24, thereby reducing the characteristic impedance to below 50Ω as a ground-added coplanar strip line.

For example, in a case where a strip width of the signal strip on the gallium arsenide substrate having a thickness of 100 micron is 50 micron, and no ground conductive areas are provided on both sides of the signal strip, the transmission line structure is a microstrip structure. In this case, the characteristic impedance is approximately 70Ω. On the other hand, as shown in FIG. 12A, in a case where the ground-added coplanar strip line is configured such that a clearance between the signal strip and the ground conductive area is 20 micron, the characteristic impedance is approximately 37Ω. Thus, the first transmission line 3 has a ground-added coplanar strip line configuration, thereby enabling the characteristic impedance of the first transmission line 3 to be reduced. Thereby, a favorable reflection characteristic can be obtained.

As shown in FIG. 12B, in order to prevent circuit characteristic of a main circuit section 26 connected to the signal strip 24 from being degraded due to the ground capacity occurring between the signal strip 24 and the ground conductive area 25, it is effective that a clearance G1 between the signal strip 24 and the ground conductive area 25a in the vicinity of the line end 27 of the signal strip 24 is made smaller than a clearance G2 in the vicinity of the main circuit section 26. That is, it is effective that the clearances between the signal strip 24 and the ground conductive areas 25a become narrower toward the end portion of the signal strip 24.

In the third embodiment, as shown in FIG. 11, the characteristic impedance of the fourth transmission line 11 is incorporated in an equivalent circuit. However, only the characteristic impedance of the first transmission line 3 may be reduced.

Needless to say, in the high-frequency circuits according to the first to third embodiments of the present invention, at the connecting portions between the respective circuits, such as at the connecting portion between the second transmission line 4 and the third transmission line 6, the strip width may be gradually changed, or a clearance between the signal strip and the ground conductive area adjacent thereto may be gradually changed, so as to gradually change a characteristic impedance of the transmission line.

### EXAMPLES

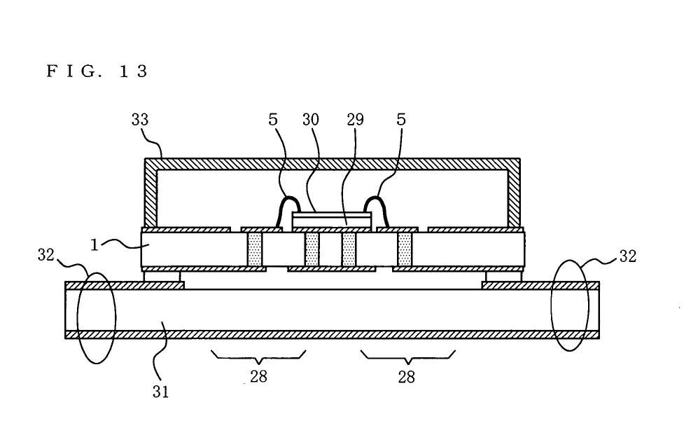

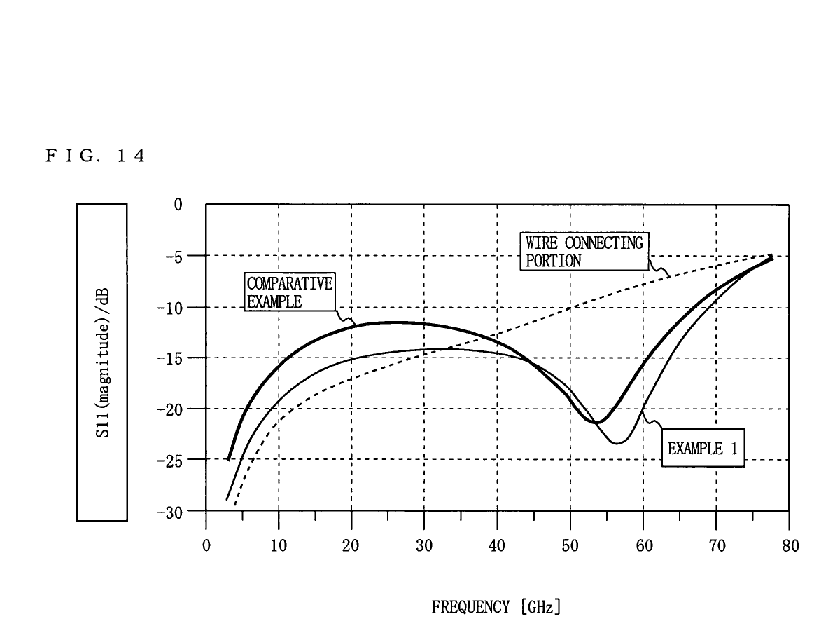

The inventor measured a transmission characteristic of the high-frequency circuit according to the present invention. FIG. 13 is an outline view illustrating a configuration of the high-frequency circuit for evaluation which is used in the measurement. In FIG. 13, the high-frequency circuit for evaluation includes a dielectric substrate 1, a gallium arsenide substrate 29 disposed on the top surface of the dielectric substrate 1, a cover 33, and a BT resin substrate 31 which is an external circuit substrate. A microstrip line 30 is formed on the top surface of the gallium arsenide substrate 29. The dielectric substrate 1 is connected to the microstrip line 30 through wires 5. A connecting portion of the microstrip line 30, the wires 5 and the dielectric substrate 1 comprise an input/output section 28 according to the high-frequency circuit configuration of the present invention. The characteristic impedance of the microstrip line 30 was 50Ω. The microstrip lines having line lengths from 0.5 mm to 5 mm were prepared in increments of 0.25 mm. A ground-added coplanar strip line 32 is formed on the top surface of the BT resin substrate 31. The BT resin substrate 31 had a thickness of 200 micron.

A high frequency probe was connected onto the ground-added coplanar strip line 32 formed on the BT resin substrate 31 to perform the measurement. A mathematical calculation was performed based on a plurality of pieces of data which had been obtained as a result of the measurement, thereby obtaining a characteristic of only the high-frequency circuit section of the present invention.

A liquid crystal polymer substrate having a thickness of 125 micron and having a copper wiring of a thickness of 40 micron formed on the top surface and the bottom surface thereof was used as the dielectric substrate 1. The liquid crystal polymer had a dielectric constant of 3 and a dielectric loss tangent of approximately 0.003.

Gold was used for a wire 5 of a diameter of 25 micron. An average value of the wire length was 320 micron. A connecting through-via formed in the liquid crystal polymer had a diameter of 280 micron.

In the high-frequency circuit for evaluation, a plurality of connecting through-vias 14 for providing connection between the respective ground conductive areas formed on the top surface and the bottom surface of the dielectric substrate 1 are formed at 400 micron intervals. Each of the top side conductive land 8 and the bottom side conductive land 9 of the via hole section 10 was a conductive area having a radius of 300 micron. A line/space ratio=100 micron/100 micron which is a standard wiring rule for a printed board was applied to perform a design. The gallium arsenide substrate 29 was covered by the cover 33 made of metal for packaging, and the measurement was performed.

Table 1 shows a parameter for a high-frequency circuit which was evaluated.

TABLE 1

| | SECOND | | | THIRD | | FOURTH | | FIRST |
|---|---|---|---|---|---|---|---|---|
| | TRANSMISSION | | | TRANSMISSION | | TRANSMISSION | | TRANSMISSION |
| | LINE | | | LINE | | LINE | | LINE |
| | | CHARACTER- | | CHARACTER- | | CHARACTER- | | CHARACTER- |
| | | ISTIC | ELECTRIC | ISTIC | ELECTRIC | ISTIC | ELECTRIC | ISTIC |
| | STRUCTURE | IMPEDANCE | LENGTH | IMPEDANCE | LENGTH | IMPEDANCE | LENGTH | IMPEDANCE |
| EXAMPLE 1 | MICROSTRIP | 35Ω | 12 | 110Ω | 13.2 | 50Ω | 30 | 50Ω |
| | LINE | | DEGREES | | DEGREES | | DEGREES | |
| EXAMPLE 2 | GROUND- | 33Ω | 15 | 110Ω | 12.8 | 50Ω | 30 | 50Ω |
| | ADDED | | DEGREES | | DEGREES | | DEGREES | |
| | COPLANAR | | | | | | | |
| | STRIP LINE | | | | | | | |
| EXAMPLE 3 | GROUND- | 33Ω | 14.8 | 110Ω | 13.6 | 90Ω | 10 | 50Ω |
| | ADDED | | DEGREES | | DEGREES | | DEGREES | |
| | COPLANAR | | | | | | | |
| | STRIP LINE | | | | | | | |
| EXAMPLE 4 | GROUND- | 33Ω | 16.2 | 135Ω | 23.5 | 50Ω | 30 | 50Ω |
| | ADDED | | DEGREES | | DEGREES | | DEGREES | |
| | COPLANAR | | | | | | | |
| | STRIP LINE | | | | | | | |
| EXAMPLE 5 | GROUND- | 33Ω | 16.2 | 135Ω | 23.5 | 90Ω | 38 | 50Ω |
| | ADDED | | DEGREES | | DEGREES | | DEGREES | |
| | COPLANAR | | | | | | | |
| | STRIP LINE | | | | | | | |
| EXAMPLE 6 | GROUND- | 33Ω | 17.9 | 110Ω | 13.4 | 50Ω | 30 | 30Ω |
| | ADDED | | DEGREES | | DEGREES | | DEGREES | |
| | COPLANAR | | | | | | | |
| | STRIP LINE | | | | | | | |
| EXAMPLE 7 | GROUND- | 33Ω | 17.3 | 135Ω | 21.6 | 90Ω | 39.2 | 30Ω |
| | ADDED | | DEGREES | | DEGREES | | DEGREES | |
| | COPLANAR | | | | | | | |
| | STRIP LINE | | | | | | | |
| DESIGN | GROUND- | 60Ω | 14 | 110Ω | 23 | 50Ω | 30 | 50Ω |
| EXAMPLE 1 | ADDED | | DEGREES | | DEGREES | | DEGREES | |
| FOR | COPLANAR | | | | | | | |
| COMPARISON | STRIP LINE | | | | | | | |
| DESIGN | GROUND- | 33Ω | 10 | 45Ω | 15 | 50Ω | 30 | 50Ω |
| EXAMPLE 2 | ADDED | | DEGREES | | DEGREES | | DEGREES | |
| FOR | COPLANAR | | | | | | | |
| COMPARISON | STRIP LINE | | | | | | | |

In example 1, the second transmission line 4 was a microstrip line.

In example 2 to example 7, and the design examples 1 and 2, the second transmission line 4 was a ground-added coplanar strip line.

In example 1 to example 3, the third transmission line 6 had the ground conductive areas 17 spaced apart from both sides of the signal strip 19 by 400 micron, respectively. Thereby, the characteristic impedance of the third transmission line 6 was set so as to have a high value of 110Ω.

In example 4 and example 5, a transmission line as shown in FIG. 5 was adopted as the third transmission line 6. That is, the ground conductive areas 17 were eliminated from both sides of the signal strip 19. The ground conductive areas 20 were formed in areas which were not opposite to the signal strip 19 on the bottom surface of the dielectric substrate 1, the ground conductive areas 20 being spaced apart from each other by 900 micron. Thereby, the characteristic impedance of the third transmission line 6 was set so as to have a high value of 135Ω.

In example 3 and example 5, the characteristic impedance of the fourth transmission line 11 was set so as to have a high value of 90Ω.

In example 6, ground pads were spaced apart from both sides of a main signal line by a width of 20 micron such that the wire connecting portion of the first transmission line 3 had a GSG-type ground-added coplanar strip line structure. Thereby, the characteristic impedance of the first transmission line 3 was 30Ω in the areas in which provided are the pads having a length of 80 micron in the signal transmission direction.

In example 7, the first transmission line 3 had the same characteristic impedance and line structure as described for example 6, the second transmission line 4 had the same characteristic impedance and line structure as described for example 2, the third transmission line 6 had the same characteristic impedance and line structure as described for example 4, and the fourth transmission line 11 had the same characteristic impedance and line structure as described for example 3.

In the design example 1 for comparison, the characteristic impedance of the second transmission line 4 was set as 60Ω so as to have a value greater than or equal to 50Ω.

In the design example 2 for comparison, the characteristic impedance of the third transmission line 6 was set as 45Ω so as to have a value smaller than or equal to 50Ω.

As a comparative example using a conventional art (not shown in Table 1), a high-frequency circuit in which a ground-added coplanar strip line on a dielectric substrate was connected to a microstrip line on a gallium arsenide substrate by a wire was used. The ground-added coplanar strip line is designed so as to shift from low impedance line to high impedance line, the ground-added coplanar strip line being connected to the via hole section designed so as to be matched to 50Ω. As the via hole section, a via hole section having a favorable reflection loss characteristic of minus 15 dB or less at up to 70 GHz by itself was used. In the comparative example, as in the examples of the present invention, measurement was performed to make mathematical calculation based on a plurality of data which had been obtained as a result of the measurement, thereby obtaining characteristic of only a high-frequency circuit section of the comparative example. In the comparative example, the low impedance line in the ground-added coplanar strip line had a characteristic impedance of 26Ω and an electric length of 2.5 degrees. On the other hand, the high impedance line in the ground-added coplanar strip line had a characteristic impedance of 80Ω and an electric length of 28 degrees. These values were obtained based on an optimal circuit design. The characteristic impedance of 70Ω for the high impedance line is a maximum value which is determined based on a minimum value 100 micron for the strip width of the signal strip, the minimum value being defined by a standard wiring rule for a printed board.

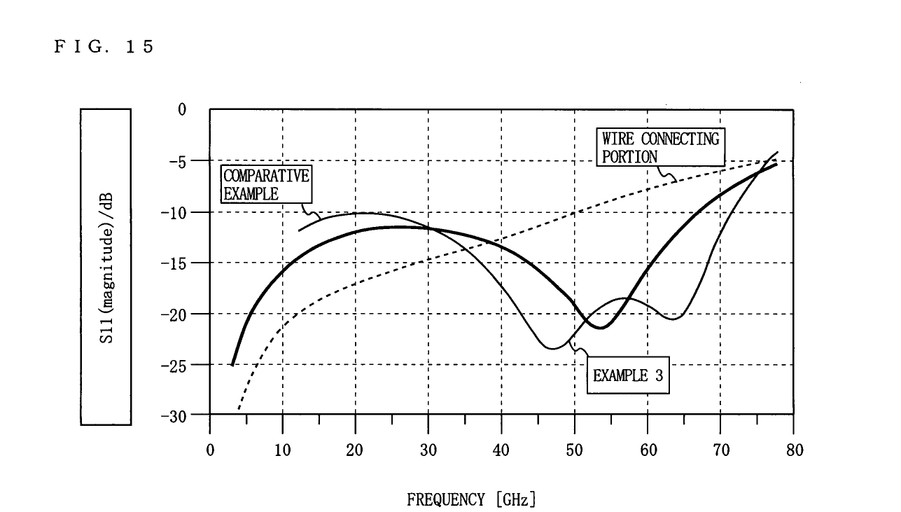

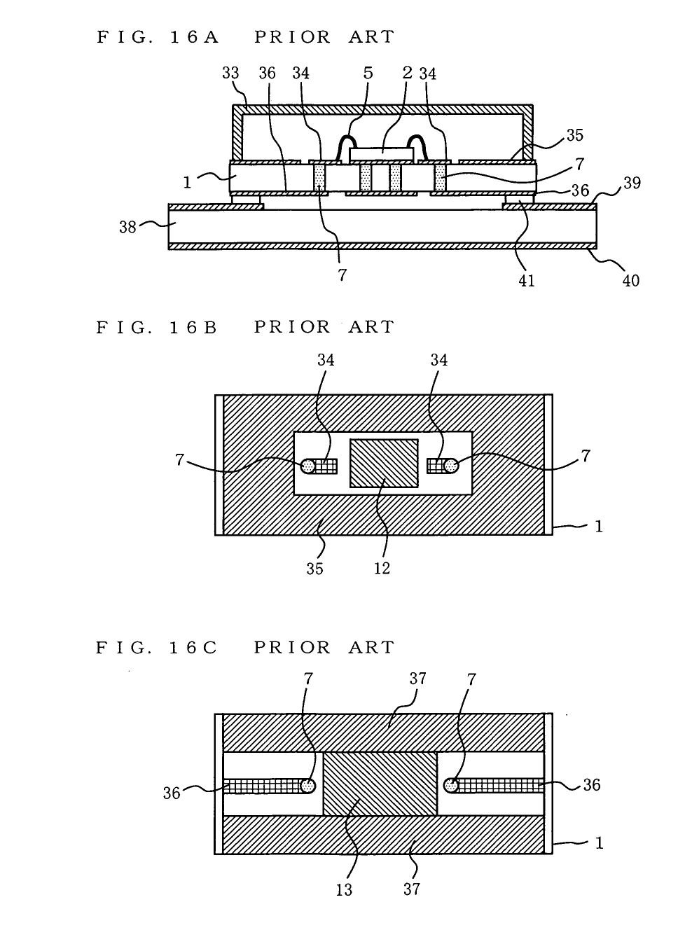

FIG. 14 is a diagram illustrating a comparison between a reflection characteristic in the comparative example and a reflection characteristic in example 1 of the present invention. FIG. 15 is a diagram illustrating a comparison between a reflection characteristic in the comparative example and a reflection characteristic in example 3 of the present invention. In FIGS. 14 and 15, the reflection characteristic of only the wire connecting portion in the case of a ground-added coplanar strip line having a signal strip width of 600 micron being used as the second transmission line 4 is shown by dotted lines.

A frequency band in which low reflection characteristic of minus 15 dB or less was able to be obtained will be described with reference to FIG. 14. The reflection characteristic of minus 15 dB or less was obtained only at 44 GHz to 61 GHz in the comparative example. On the other hand, in example 1, the reflection characteristic of minus 15 dB or less was able to be obtained at 42 GHz to 63 GHz.

Moreover, in FIG. 14, in both the comparative example and example 1, it was impossible to obtain the reflection characteristic of minus 15 dB or less around 30 GHz band. However, the worst value was minus 11.5 dB in the comparative example, whereas the low reflection characteristic having the worst value of minus 14 dB was able to be obtained in example 1. Thus, it was clear that the low reflection was able to be obtained over a wide band in example 1, and it was shown that the present invention has an effect of the wide band low reflection characteristic.

Further, although the electric length required for the transmission line of high impedance was 28 degrees in the comparative example, the electric length for the third transmission line 6 was only 13.2 degrees in example 1. Therefore, example 1 has a smaller size than the comparative example.

Moreover, in the comparative example, since a via hole section had to be additionally provided at the end part of the high impedance line, the reduction in volume of the circuit configuration was limited. In examples, however, the third transmission line 6 is a portion of a component circuit around the via hole section 10, and therefore the substantial reduction in volume can be directed.

A frequency band in which reflection characteristic of minus 15 dB or less was able to be obtained will be described with reference to FIG. 15. In the comparative example, the reflection characteristic of minus 15 dB or less was obtained only at 44 GHz to 61 GHz. On the other hand, in example 3, the reflection characteristic of minus 15 dB or less was able to be obtained at 37.5 GHz to 68 GHz. Thus, as is apparent from the comparison between example 1 and example 3, it was shown that it is effective that the fourth transmission line 11 has a characteristic impedance higher than or equal to 50Ω.

The bands in which the low reflection characteristic was able to be obtained in example 1 to example 7, the design examples 1 and 2 for comparison, and the comparative example are shown in Table 2.

TABLE 2

| | BAND IN WHICH LOW |
|---|---|
| | REFLECTION CHARACTER- |
| | ISTIC WAS ABLE TO BE OBTAINED |
| EXAMPLE 1 | 42 GHz to 63 GHz |
| EXAMPLE 2 | 41 GHz to 65 GHz |
| EXAMPLE 3 | 37.5 GHz to 68 GHz |
| EXAMPLE 4 | 41 GHz to 66.5 GHz |
| EXAMPLE 5 | 35.5 GHz to 70 GHz |
| EXAMPLE 6 | 42 GHz to 62 GHz |
| EXAMPLE 7 | 18 GHz to 77 GHz |
| DESIGN EXAMPLE 1 | 49 GHz to 60 GHz |
| FOR COMPARISON | |
| DESIGN EXAMPLE 2 | NOT OBTAINED |
| FOR COMPARISON | |
| COMPARATIVE EXAMPLE | 44 GHz to 61 GHz |

As is shown in Table 2, it was clear that the reflection characteristics were improved also in examples 2, 4, 5, 6, and 7 in addition to examples 1 and 3 as compared to the comparative example. Particularly, in example 7, the most favorable result was able to be obtained. In example 7, the reflection characteristic of minus 15 dB or less was able to be obtained over a very wide band from 18 GHz to 77 GHz. Thereby, it was proved that it is most effective that the second transmission line 4 has the characteristic impedance lower than or equal to 50Ω, the third transmission line 6 has the characteristic impedance higher than or equal to 50Ω, and the fourth transmission line 11 has the characteristic impedance higher than or equal to 50Ω.

On the other hand, in the design example 1 for comparison, the low reflection characteristic was obtained only in a narrow band from 49 GHz to 60 GHz. Further, in the design example 2 for comparison, the low reflection characteristic was not able to be obtained in any band. In the example for comparison, a frequency at which the characteristic of the lowest reflection was obtained was 54 GHz, and at that time the reflection intensity was minus 14 dB.

As described above, the useful effect of the present invention was shown based on the comparison in characteristic among the comparative example of a high-frequency circuit of a conventional configuration, the design examples for comparison, and examples of the high-frequency circuit of the present invention.

While as described above, the present invention is described in detail, the foregoing description is in all aspects illustrative of the invention and does not restrict the scope of the invention. Needless to say, numerous modifications and variations can be devised without departing from the scope of the invention.

The high-frequency circuit according to the present invention is capable of realizing low reflection over wide bands, and is useful when used in the adjacent portions to which the high-frequency functional element is wire-bonded, and the like.

1. A high-frequency circuit having a high-frequency functional element mounted on a dielectric substrate, comprising:
a first transmission line formed in the high-frequency functional element and including a first signal strip and a first ground conductive area;
a second transmission line having a characteristic impedance lower than or equal to 50Ω, and including a second signal strip and a second ground conductive area, the second signal strip formed on a top surface side of the dielectric substrate;
a wire for connecting between the first signal strip and the second signal strip;
a third transmission line having a characteristic impedance higher than 50Ω, and including a third signal strip and a third ground conductive area, the third signal strip connected to the second signal strip, the third signal strip and the third ground conductive area formed on the top surface side of the dielectric substrate;
a via hole section including a connecting through-via formed so as to pass through the dielectric substrate, a top side conductive land connected to the connecting through-via and the third signal strip, and a bottom side conductive land provided on a bottom surface side of the dielectric substrate and connected to the connecting through-via; and
a fourth transmission line having a characteristic impedance higher than or equal to 50Ω in at least a portion of an area thereof, and including a fourth signal strip and a fourth ground conductive area provided adjacent to the fourth signal strip and the bottom side conductive land, the fourth signal strip connected to the bottom side conductive land, the fourth signal strip and the fourth ground conductive area formed on the bottom surface side of the dielectric substrate, wherein
the third ground conductive area is not formed in an area on the bottom surface side of the dielectric substrate and opposite to the third signal strip formed on the top surface side of the dielectric substrate;
in the fourth transmission line, the fourth ground conductive area is not formed in an area on the top surface side of the dielectric substrate and opposite to the fourth signal strip formed on the bottom surface side of the dielectric substrate; and
an LCLCL low pass filer is configured therefrom.

2. The high-frequency circuit according to claim 1, wherein
the first transmission line has a characteristic impedance lower than or equal to 50Ω at a connecting portion between the wire and the first transmission line.

3. The high-frequency circuit according to claim 2, wherein the first transmission line has a coplanar-type GSG pad at the connecting portion between the wire and the first transmission line.

4. The high-frequency circuit according to claim 3, wherein a ground conductive pad contained in the pad is adjacent to the first signal strip in the first transmission line.

5. The high-frequency circuit according to claim 4, wherein a clearance between the first signal strip and the ground conductive pad is narrower toward an end portion of the first signal strip in the first transmission line.

6. The high-frequency circuit according to claim 1, wherein the second transmission line is a ground-added coplanar strip line.

7. The high-frequency circuit according to claim 1, wherein
in the third transmission line,
on the bottom surface of the dielectric substrate, the third ground conductive area is formed in areas other than an area opposite to the third signal strip formed on the top surface side of the dielectric substrate.

8. The high-frequency circuit according to claim 1, wherein a dielectric constant of a dielectric comprising the dielectric substrate is smaller than or equal to 5.

9. The high-frequency circuit according to claim 1, wherein a strip width of the third signal strip is smaller than a strip width of the second signal strip.

10. The high-frequency circuit according to claim 1, wherein the second transmission line has a characteristic impedance lower than or equal to 45Ω.

11. The high-frequency circuit according to claim 1, wherein the third transmission line has a characteristic impedance higher than or equal to 110Ω.
